(19) United States
(12) Patent Application Publication
(10) Pub. No.: US 2025/0192615 A1
(43) Pub. Date: Jun. 12, 2025

(54) WIRELESS POWER TRANSMISSION DEVICE COMPRISING IMPEDANCE MATCHING CIRCUIT, AND WIRELESS POWER TRANSMISSION METHOD

(71) Applicant: Samsung Electronics Co., Ltd., Suwon-si, (KR)

(72) Inventors: Beomwoo GU, Suwon-si (KR); Jaeseok PARK, Suwon-si (KR); Jaehyun PARK, Suwon-si (KR); Kangho BYUN, Suwon-si (KR); Sungku YEO, Suwon-si (KR)

(21) Appl. No.: 19/054,276

(22) Filed: Feb. 14, 2025

Related U.S. Application Data
(63) Continuation of application No. PCT/KR2023/008785, filed on Jun. 23, 2023.

(30) Foreign Application Priority Data
Aug. 23, 2022 (KR) 10-2022-0105586

(51) Int. Cl. H02J 50/12; H03F 1/56; H03F 3/24

(52) U.S. Cl. CPC H02J 50/12; H03F 1/56; H03F 3/245; H03F 2200/387; H03F 2200/451

(57) ABSTRACT

A wireless power transmission device is provided. The wireless power transmission device includes a power source, a first power amplifier configured to provide a first radio frequency (RF) signal based on a driving voltage provided from the power source, a transmission coil configured to be used to transmit power to an outside based on the first RF signal, a matching circuit configured to provide impedance matching between the transmission coil and the first power amplifier, and a bias circuit configured to provide a bias voltage to the matching circuit, wherein an input terminal of the bias circuit is connected to a first terminal of a first transistor included in the first power amplifier, wherein an output terminal of the bias circuit is connected to a second terminal of a second transistor included in the matching circuit, and wherein the bias circuit is configured to provide the bias voltage to the second terminal of the second transistor based on the first RF signal at the first terminal of the first transistor.

### CROSS-REFERENCE TO RELATED APPLICATION(S)

This application is a continuation application, claiming priority under 35 U.S.C. § 365(c), of an International application No. PCT/KR2023/008785, filed on Jun. 23, 2023, which is based on and claims the benefit of a Korean patent application number 10-2022-0105586, filed on Aug. 23, 2022, in the Korean Intellectual Property Office, the disclosure of which is incorporated by reference herein in its entirety.

### BACKGROUND

### 1. Field

The disclosure relates to a wireless power transmission device including an impedance matching circuit and a wireless power transmission method.

### 2. Description of Related Art

Wireless charging technology adopts wireless power transmission/reception. For example, wireless charging may automatically charge the battery of a mobile phone by placing the mobile phone on or near a wireless power transmitter (e.g., a charging pad) without connection via a separate charging connector. Wireless communication technology eliminates the need for a connector for supplying power to electronics, thus providing enhanced waterproofing, and also requires no wired charger to thus provide better portability.

As wireless charging technology develops, there is ongoing research for methods for charging other various electronic devices (wireless power reception device) by supplying power to the other electronic devices by an electronic device (wireless power transmission device). For example, wireless charging comes in a few different types, such as of electromagnetic induction using a coil, resonance, and radio frequency (RF)/microwave radiation that converts electrical energy into microwaves and transfers the microwaves.

For example, wireless charging techniques using electromagnetic induction or resonance are recently being widely adopted for electronic devices, such as smartphones. For example, if a power transmitting unit (PTU) (e.g., a wireless power transmitter) and a power receiving unit (PRU) (e.g., a smartphone or a wearable electronic device) come in contact or close to each other within a predetermined distance, power may be transferred to the power receiving unit by an electromagnetic induction or electromagnetic resonance method between the transmission coil or resonator of the power transmitting unit and the reception coil or resonator of the power receiving unit, and the battery included in the power receiving unit may be charged with the transferred power.

The wireless power transmission device (or power transmitting unit) may include an inverter (e.g., a power amplifier) and a resonator. The inverter is a device that converts direct current (DC) power into alternating current (AC) power. To increase the efficiency of the inverter, various matching circuits may be connected to an output terminal of the inverter.

As an example of the inverter, there is a class E inverter (or a class E power amplifier (PA)). Since the class E inverter operates under a zero-voltage switching (ZVS) condition and a zero-derivative voltage switching (ZDS) condition, there is an advantage in that it may be efficiently operated at a high (e.g., 1 MHz or higher) switching frequency.

According to an embodiment, to increase the efficiency of the class E inverter, there is used a class EFₙ (where n is an integer of 2 or more) inverter or a class E/Fₙ inverter adding a resonant network in parallel to the load network.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a wireless power transmission device including an impedance matching circuit and a wireless power transmission method.

Additional aspects will be set forth in part in the description which follows and, in part, will be apparent from the description, or may be learned by practice of the presented embodiments.

In accordance with an aspect of the disclosure, a wireless power transmission device is provided. The wireless power transmission device includes a power source, a first power amplifier configured to provide a first radio frequency signal based on a driving voltage provided from the power source, a transmission coil configured to be used to transmit power to an outside based on the first RF signal, a matching circuit configured to provide impedance matching between the transmission coil and the first power amplifier, and a bias circuit configured to provide a bias voltage to the matching circuit, wherein input terminal of the bias circuit is connected to a first terminal of a first transistor included in the first power amplifier, wherein an output terminal of the bias circuit is connected to a second terminal of a second transistor included in the matching circuit, and wherein the bias circuit is configured to provide the bias voltage to the second terminal of the second transistor based on the first RF signal at the first terminal of the first transistor.

In accordance with another aspect of the disclosure, a wireless power transmission device is provided. The wireless power transmission device includes a power source, a first power amplifier configured to provide a first radio frequency signal based on a driving voltage provided from the power source, a transmission coil configured to be used to transmit power to an outside based on the first RF signal, a matching circuit configured to provide impedance matching between the transmission coil and the first power amplifier, and a converter configured to provide a bias voltage to the matching circuit. An input terminal of the converter may be connected to the power source. An output terminal of the converter may be connected to a transistor included in the matching circuit.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a circuit diagram illustrating a wireless power transmission device according to an embodiment of the disclosure;

FIG. 2 is a circuit diagram illustrating a wireless power transmission device according to an embodiment of the disclosure;

FIG. 3 is a circuit diagram illustrating a wireless power transmission device according to an embodiment of the disclosure;

FIG. 4 is a circuit diagram illustrating a wireless power transmission device according to an embodiment of the disclosure;

FIG. 5 is a block diagram illustrating a wireless power transmission device according to an embodiment of the disclosure;

FIG. 6 is a view illustrating a switch voltage according to an embodiment of the disclosure;

FIG. 7 is a view illustrating a relationship between a switch voltage and a parasitic capacitance according to an embodiment of the disclosure;

FIG. 8 is a view illustrating a switch voltage according to an embodiment of the disclosure;

FIG. 9 is a block diagram illustrating a wireless power transmission device according to an embodiment of the disclosure;

FIG. 10 is a block diagram illustrating a wireless power transmission device according to an embodiment of the disclosure;

FIG. 11 is a block diagram illustrating a wireless power transmission device according to an embodiment of the disclosure;

FIG. 12 is a circuit diagram illustrating a bias circuit according to an embodiment of the disclosure;

FIG. 13 is a circuit diagram illustrating a wireless power transmission device according to an embodiment of the disclosure;

FIG. 14 is a block diagram illustrating a wireless power transmission device according to an embodiment of the disclosure;

FIG. 15 is a circuit diagram illustrating a bias circuit according to an embodiment of the disclosure;

FIG. 16 is a view illustrating an over-voltage protection circuit and a voltage sensor according to an embodiment of the disclosure; and

FIG. 17 is a view illustrating an over-voltage protection circuit according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

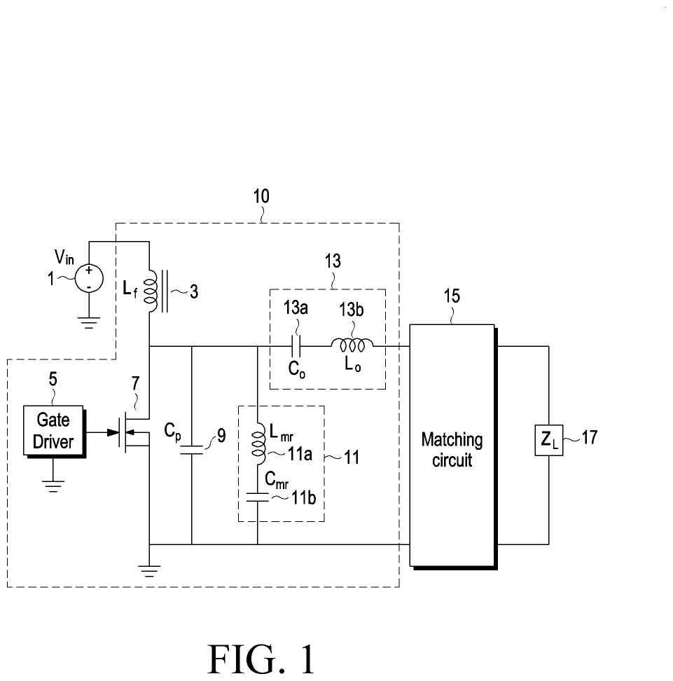

FIG. 1 is a circuit diagram illustrating a wireless power transmission device according to an embodiment of the disclosure.

Referring to FIG. 1, a wireless power transmission device (e.g., the wireless power transmission device 500 described below) may include a power amplifier 10 (e.g., an EF2 inverter), a matching circuit 15, and a load 17. In the disclosure, the terms “power amplifier” and “inverter” may be used interchangeably.

According to an embodiment, the power amplifier 10 may include an RF choke inductor (Lf) 3, a gate driver 5, a transistor 7, a shunt capacitor (Cp) 9, a first LC resonance circuit 11, and a second LC resonance circuit 13.

The transistor 7 may receive a DC voltage Vin, as a driving voltage, from an input power source 1 and operate. The transistor 7 may receive a pulsed (e.g., square wave) input signal through the input terminal (e.g., gate) from a gate driver 5, turning on or off. The transistor 7 may include a metal oxide semiconductor field effect transistor (MOSFET). Hereinafter, “transistor” may be a MOSFET, but is not limited thereto.

The RF choke inductor 3 may cut off transfer of an RF signal from the input power source 1 to the transistor 7 so that only DC current is transferred to the transistor 7.

The shunt capacitor 9 may be connected in parallel with the transistor 9 and be discharged or charged while the transistor 7 is on or off. The shunt capacitor 9 may be a separate capacitor connected in parallel with the transistor 7, and may be described as including an internal capacitance (e.g., drain-source capacitance Cds) of the transistor 2.

An RF signal (or RF power) may be generated based on the turn-on or off of the transistor 7 by receiving an input signal from the gate driver 5. The generated RF signal may be a signal having an operating frequency corresponding to the input signal input from the gate driver 5 to the gate of the transistor 7. For example, when the wireless power transmission device transmits wireless power according to a resonance scheme standard, the operating frequency may be 6.78 MHz, but is not limited thereto. The RF signal or RF power may be transferred to the first LC resonance circuit 11 and/or the second LC resonance circuit 13 through the output terminal of the transistor 7. More specifically, if the transistor 7 is turned on (e.g., if the transistor 7 is saturated), the transistor 7 may be electrically shorted and be interpreted as a short circuit for the ground connected with the source, and the voltage of the output terminal may be interpreted as 0. As the transistor 7 is turned on, the current flowing through the RF chock inductor 3 to the transistor 7 may gradually increase. Thereafter, if the transistor 7 is turned off, the current flowing through the RF choke inductor 3 may be oriented to the shunt capacitor 9 and, as the shunt capacitor 9 is gradually charged, the voltage at the output terminal of the transistor 7 (e.g., the voltage between both the terminals of the shunt capacitor 9) may increase as it reaches the maximum value. Thereafter, as the shunt capacitor 9 is gradually discharged, current flows from the shunt capacitor 9 through the output terminal of the transistor 7 to the first LC resonance circuit 11 and/or the second LC resonance circuit 13, so that the voltage between both the terminals of the shunt capacitor 9 ma gradually decrease. The transistor 7, the shunt capacitor 9, and the input signal may be set so that before the transistor 7 turns off and then turns back on (e.g., before current starts to flow again through the RF choke inductor 3 to the transistor 7), the voltage at the output terminal of the transistor 7 (e.g., the voltage between both the terminals of the shunt capacitor 9 and the drain-source voltage of the transistor 7) may gradually decrease to 0, and the variation in the reduction of the voltage at the output terminal of the transistor 7 is 0. Thereafter, if the transistor 7 is turned back on, the current flowing through the RF choke inductor 3 may be oriented to the transistor 7 and, while the transistor 7 is on, the voltage at the output terminal of the transistor 7 may remain 0. As described above, while the transistor 7 is in an on state, the voltage at the output terminal of the transistor 7 is 0 and, while the transistor 7 is in an off state, the current flowing through the RF choke inductor 3 is oriented to the shunt capacitor 9, so that the current flowing through the RF choke inductor 3 to the transistor 7 is 0 (in other words, since the period during which the voltage at the output terminal of the transistor 7 is not zero (non-zero) does not overlap the period during which the drain-source current is not zero). Thus, the power consumed from the transistor 7 may be ideally zero. However, in a non-ideal case, since the transistor 7 generates RF power based on being turned on or off, the generated RF power has a second and higher harmonic frequency components, as well as the desired frequency component (e.g., the fundamental component of the operating frequency). The duty cycle of the transistor 7 may be set to, e.g., 50%, based on the input signal.

The first LC resonance circuit 11 may be connected in parallel with the transistor 7. The first LC resonance circuit 11 may include a first inductor (Lmr) 11a (e.g., a coil) and a first capacitor (Cmr) 11b connected in series with each other. The first inductor 11a and the first capacitor 11b may have proper element values that allow the resonant frequency of the first LC resonance circuit 11 to correspond to the second harmonic frequency (2fs) of the operating frequency (fs) of the input signal. The first LC resonance circuit 11 may be interpreted electrically as a short circuit at the second harmonic frequency (2fs). The first LC resonance circuit 11 may be operated as a second harmonic filter (e.g., a band-stop filter) that prevents the second harmonic component of the RF power generated from the transistor 7 from being transferred to the second LC resonance circuit 13 based on being electrically shorted at the second harmonic frequency (2fs).

The second LC resonance circuit 13 may be connected in series to the output terminal of the transistor 7. The second LC resonance circuit 13 may include a second capacitor (Co) 13a and a second inductor (Lo) 13b connected in series with each other. The second capacitor 13a and the second inductor 13b may have proper element values that allow the resonant frequency of the second LC resonance circuit 13 to correspond to the operating frequency (fs) of the input signal (e.g., to correspond to the fundamental frequency (or the first harmonic frequency) (fs)). The second LC resonance circuit 13 may be interpreted electrically as a short circuit at the first harmonic frequency (fs). The second LC resonance circuit 13 may be operated as a band-pass filter (or low-pass filter) that passes the fundamental component (or first harmonic component) (e.g., the component corresponding to the operating frequency) of the RF power generated from the transistor 7 based on being electrically shorted at the first harmonic frequency (fs).

The matching circuit 15 may be connected in series to the second LC resonance circuit 13. A harmonic filter for filtering harmonic components may be disposed between the matching circuit 15 and the second LC resonance circuit 13. The matching circuit 15 may provide impedance matching that allows the output impedance (e.g., the impedance to the second LC resonance circuit 13) to match the impedance of the load (ZL) 17. The matching circuit 15 may include, e.g., at least one low-pass filter and/or a band-stop filter, and the low-pass filter may include at least one capacitor.

The load 17 may include at least one hardware component (e.g., a circuit element) that receives the RF power generated by the EF2 inverter 10 or receives the RF power and operates. For example, the load 17 may include a hardware component (e.g., a transmission coil) of the wireless power transmission device (e.g., the electronic device) including the power amplifier 10 and/or a reception device (e.g., the wireless power reception device or power receiving unit) receiving power from the magnetically coupled electronic device. For example, if the metal (e.g., power transmitting unit) approaches the power amplifier 10 or the wireless power transmission device including the power amplifier 10, the coupling therebetween may increase, and the impedance ZL toward the load 17 may increase, so that the efficiency of the EF2 inverter 10 or the wireless power transmission device may be deteriorated.

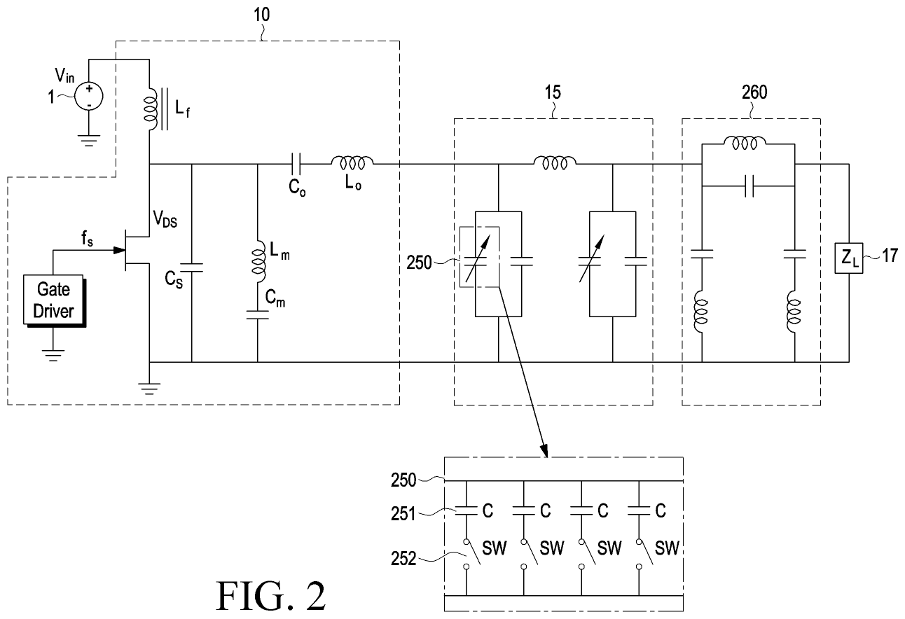

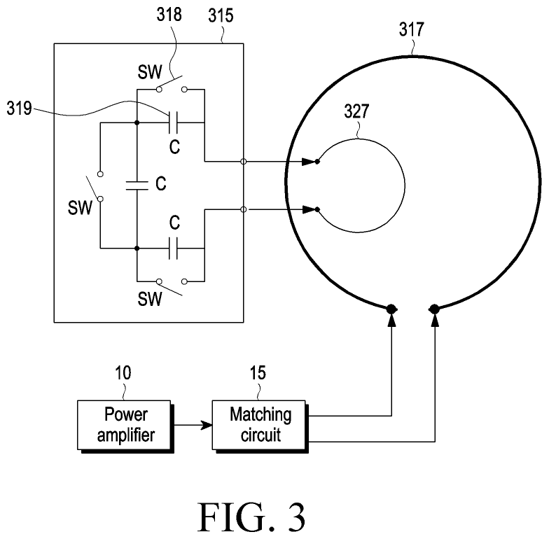

FIG. 2 is a circuit diagram illustrating a wireless power transmission device according to an embodiment of the disclosure. FIG. 3 is a circuit diagram illustrating a wireless power transmission device according to an embodiment of the disclosure.

An impedance compensation method according to an embodiment may be understood with reference to FIGS. 2 and 3. FIG. 2 is a view illustrating a capacitor bank scheme. FIG. 3 is a view illustrating an auxiliary coil scheme. The matching circuit disclosed in FIGS. 2 and 3 is exemplary, and the configuration of the matching circuit is not limited.

Referring to FIG. 2, a wireless power transmission device (e.g., the wireless power transmission device 500 described below) may include a power amplifier 10, a matching circuit 15, and a load 17. The description of the power amplifier 10 overlaps the description of FIG. 1 and is therefore omitted.

The load 17 may include a resonator. The load 17 may include a transmission coil. In the disclosure, the load 17, resonator, or transmission coil may be used interchangeably.

A harmonic filter 260 may additionally be disposed between the matching circuit 15 and the load 17. The harmonic filter 260 may operate as a band stop filter that prevents high-order harmonic components (e.g., 3rd, 5th, 7th harmonic components) from being transferred to the load 17.

The matching circuit 15 may include a plurality of capacitors. Referring to FIG. 2, the matching circuit 15 may include a capacitor bank structure in which a plurality of capacitors are connected in parallel and a switch (e.g., a transistor) is connected in series to each capacitor. The variable capacitor 250 included in the matching circuit 15 may include a plurality of capacitors (e.g., a plurality of capacitors including a first capacitor 251) and a plurality of switches (e.g., a plurality of switches including a first switch 252 (e.g., a transistor). Descriptions of each capacitor and each switch included in the variable capacitor 250 are similar, and the first capacitor 251 and the first switch 252 are described as a representative.

The impedance of the variable capacitor 250 may be changed according to the on/off of the first switch 252. The wireless power transmission device may perform impedance matching through the matching circuit 15 by controlling a switch (e.g., the first switch 252) included in the matching circuit 15 of the wireless power transmission device.

Referring to FIG. 3, a wireless power transmission device (e.g., the wireless power transmission device 500 described below) may include a power amplifier 10, a matching circuit 15, and a transmission coil 317. Descriptions of the power amplifier 10 and the matching circuit 15 overlap those of FIG. 1, and thus will be omitted.

Referring to FIG. 3, the wireless power transmission device may wirelessly transmit power to the outside through a transmission coil 317. The wireless power transmission device may include an auxiliary coil 327 that may be magnetically coupled to the transmission coil. The wireless power transmission device may include an auxiliary matching circuit 315. The auxiliary matching circuit 315 may be connected to the auxiliary coil 327 to perform impedance matching.

Referring to FIG. 3, the auxiliary matching circuit 315 may include a plurality of capacitors (e.g., a plurality of capacitors including a second capacitor 319) and a plurality of switches (e.g., a plurality of switches including a second switch 318 (e.g., a transistor). Descriptions of each capacitor and each switch included in the auxiliary matching circuit 315 are similar, and the second capacitor 319 and the second switch 318 are described as a representative.

The impedance of the auxiliary matching circuit 315 may be changed according to the on/off of the second switch 318. The wireless power transmission device may perform impedance matching through the auxiliary matching circuit 315 by controlling a switch (e.g., the second switch 318) included in the auxiliary matching circuit 315 of the wireless power transmission device.

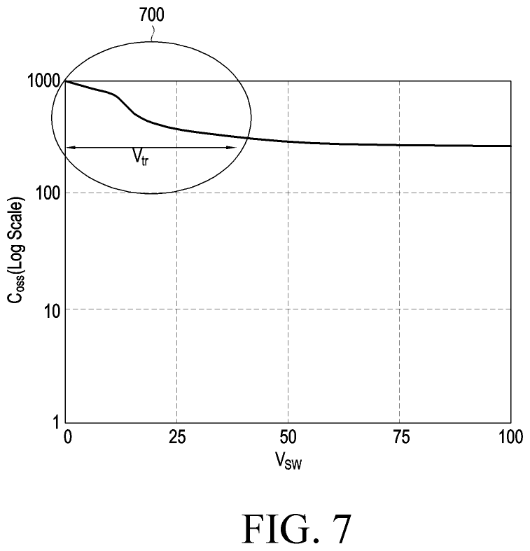

The first switch 252 of FIG. 2 and the second switch 318 of FIG. 3 may include a transistor (e.g., metal oxide semiconductor field effect transistor (MOSFET). When the switch is turned off, the capacitance of the parasitic capacitor inside the switch (e.g., the transistor) may vary greatly at a voltage in a specific range. When the first switch 252 of FIG. 2 or the second switch 318 of FIG. 3 includes a transistor, a harmonic of the circuit may be increased by the internal parasitic capacitor Cₒₛₛ of the first switch 252 or the second switch 318 when the switch is turned off. The parasitic capacitor is described below with reference to FIGS. 6 and 7.

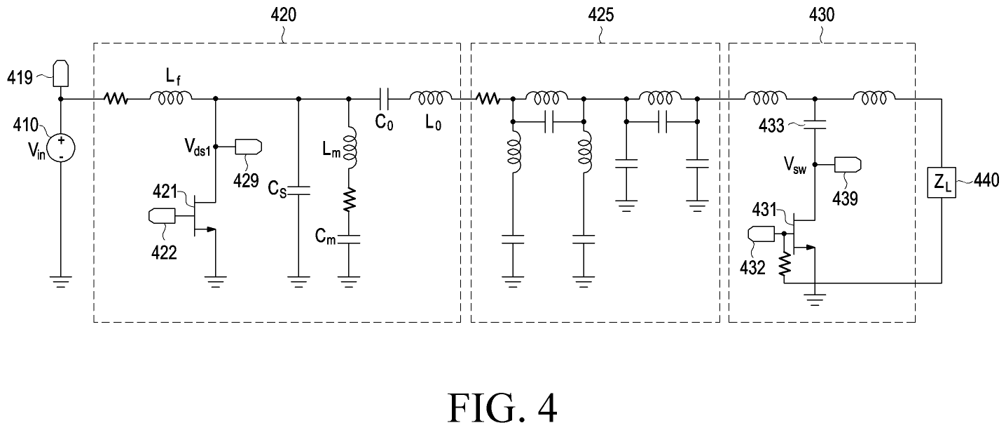

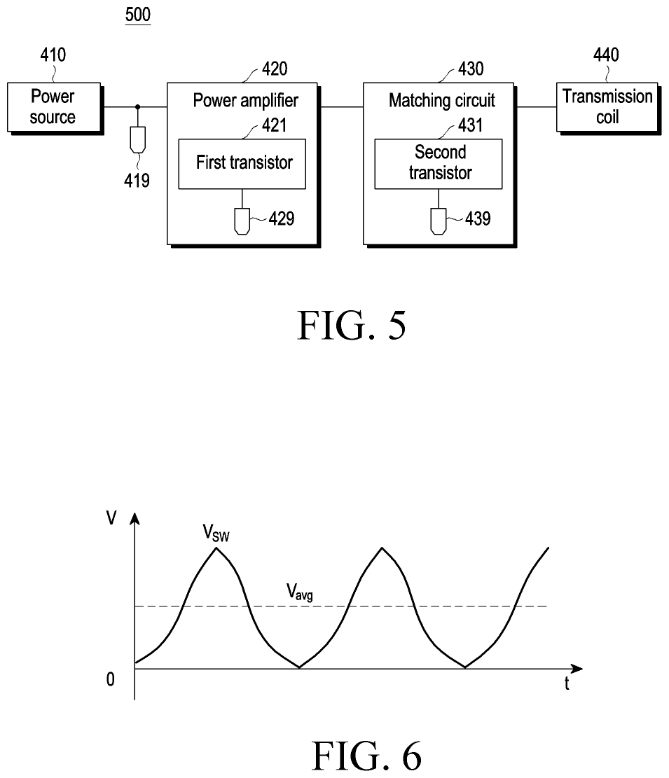

FIG. 4 is a circuit diagram illustrating a wireless power transmission device according to an embodiment of the disclosure. FIG. 5 is a block diagram illustrating a wireless power transmission device according to an embodiment of the disclosure.

FIG. 4 is merely an example of a circuit diagram of a wireless power transmission device (e.g., the wireless power transmission device 500 of FIG. 5), and the circuit diagram of the wireless power transmission device is not limited to FIG. 4.

Referring to FIG. 4, a wireless power transmission device (e.g., the wireless power transmission device 500 of FIG. 5) may include a power source 410 (e.g., the input power source 1 of FIG. 1), a power amplifier 420 (e.g., the power amplifier 10 of FIG. 1), a harmonic filter 425, a matching circuit 430, and/or a transmission coil 440.

The harmonic filter 425 of FIG. 4 may not be included in the wireless power transmission device or may be connected to a position different from that of FIG. 4. The transmission coil 440 may be understood as a resonator 440 including a transmission coil 440 or a load 440 including the transmission coil 440. The transmission coil 440 may be a transmission coil included in the load 17 of FIG. 1. Hereinafter, for convenience of description, it will be referred to as a transmission coil 440. The matching circuit 430 may provide impedance matching that allows the output impedance (e.g., the impedance viewed from the transmission coil 440 (e.g., the load 440)) to match the impedance of the transmission coil 440 (e.g., the load 440).

The power amplifier 420 of FIG. 4 may be the power amplifier 10 of FIG. 1. The power amplifier 420 may include a first transistor 421 (e.g., the transistor 7 in FIG. 1) and a first gate driver 422 (e.g., the gate driver 5 in FIG. 1). The description of the transistor and the gate driver may be understood with reference to the description of FIG. 1. The first transistor 421 may be a MOSFET, but there is no limitation on the type of the first transistor 421. Referring to FIG. 4, the voltage of the output terminal 429 (e.g., the first terminal) of the first transistor 421 may be referred to as a first drain-source voltage (e.g., “V_{ds1}”). In FIG. 4, the symbol corresponding to the output terminal 429 may be understood to describe that another circuit may be connected to the output terminal 429 of the first transistor 421. The remaining components included in the power amplifier 420 may be understood similarly to the components included in the power amplifier 10 of FIG. 1. The power amplifier 420 may provide a radio frequency (RF) signal based on a driving voltage provided from the power source 410. The wireless power transmission device (e.g., the wireless power transmission device 500 of FIG. 5) may transmit power to the outside through the transmission coil 440 based on the radio frequency (RF) signal provided from the power amplifier 420.

The matching circuit 430 of FIG. 4 may provide impedance matching between the transmission coil 440 and the power amplifier 420. The matching circuit 430 may include a second transistor 431 and a second gate driver 432. The description of the transistor and the gate driver may be understood with reference to the description of FIG. 1. The second transistor 431 may be a MOSFET, but there is no limitation on the type of the second transistor 431. Referring to FIG. 4, the voltage (e.g., the drain-source voltage) of the output terminal 439 (e.g., the second terminal) of the second transistor 431 may be referred to as a switch voltage (e.g., “V_{sw},”). In FIG. 4, the symbol corresponding to the output terminal 439 may be understood to describe that another circuit may be connected to the output terminal 439 of the second transistor 431. The matching circuit 430 of FIG. 4 may include a shunt capacitor 433 connected to an output terminal 439 (e.g., the second terminal) of the second transistor 431. The shunt capacitor 433 may correspond to the first capacitor 251 of FIG. 2. The second transistor 431 may correspond to the first switch 252 of FIG. 2. The shunt capacitor 433 may be switched according to the second transistor 431. By the shunt capacitor 433, the effect of a DC voltage (e.g., the bias voltage described below) provided to the output terminal 439 of the second transistor 431 may be blocked. For example, even if a bias voltage (e.g., a DC voltage) is provided by another circuit connected to the output terminal 439 of the second transistor 431, the effect of the bias voltage may be blocked by the shunt capacitor 433.

The power source 410 may provide a driving voltage to the power amplifier 420. The power source 410 is a component that provides a driving voltage to the power amplifier 420, and there is no limitation on the implementation method of the power source 410. In FIG. 4, the symbol corresponding to one end 419 of the power source 410 may be understood to describe that another circuit may be connected to the one end 419 of the power source 410.

The wireless power transmission device 500 of FIG. 5 may be the wireless power transmission device of FIG. 1, the wireless power transmission device of FIG. 2, the wireless power transmission device of FIG. 3, or the wireless power transmission device of FIG. 4.

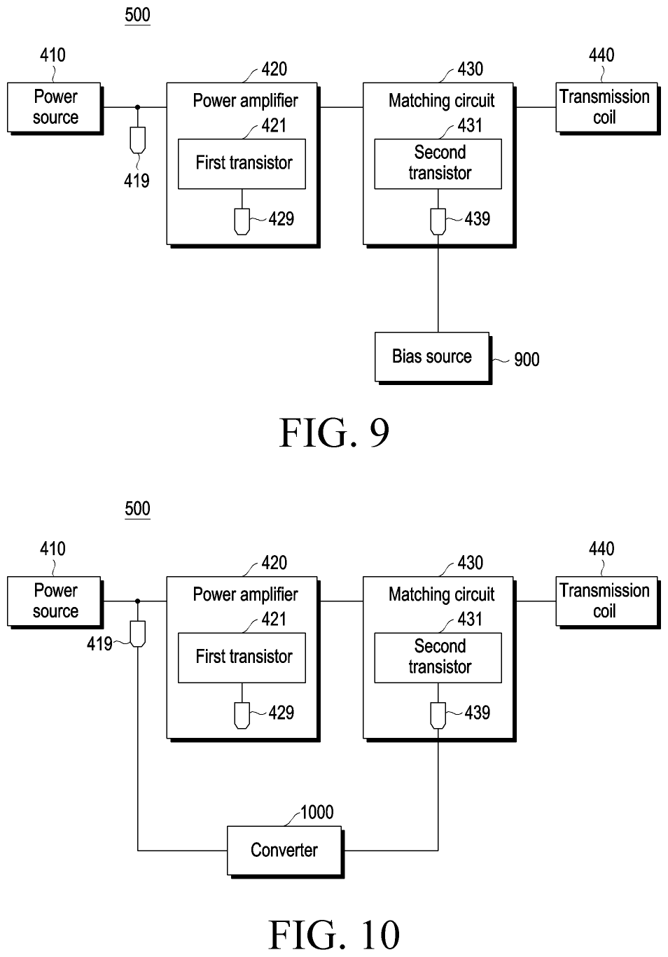

Referring to FIGS. 4 and 5, the wireless power transmission device 500 may include a power source 410, a power amplifier 420, a matching circuit 430, and a transmission coil 440. In FIG. 5, symbols 419, 429, and 439 for describing that another circuit may be connected to the output terminal 429 (e.g., the first terminal) of the first transistor 421 included in the power amplifier 420, the output terminal 439 (e.g., the second terminal) of the second transistor 431 included in the matching circuit 430, or one end 419 of the power source 410 are shown. The connection relationship of other circuits is described with reference to FIGS. 9 to 17.

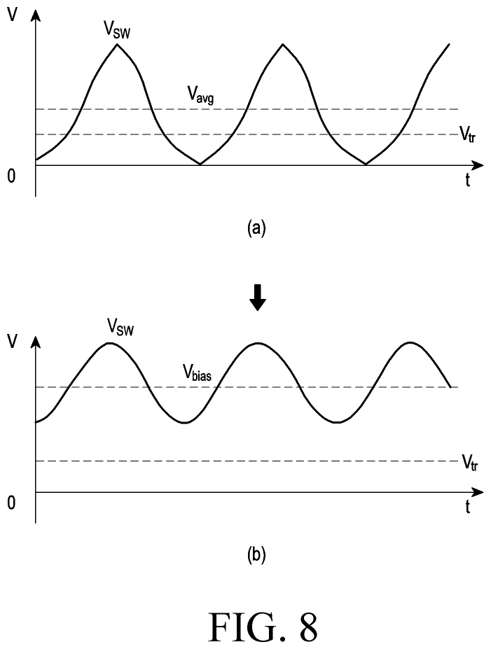

FIG. 6 is a view illustrating a switch voltage according to an embodiment of the disclosure. FIG. 7 is a view illustrating a relationship between a switch voltage and a parasitic capacitance according to an embodiment of the disclosure. FIG. 8 is a view illustrating a switch voltage according to an embodiment of the disclosure.

The switch voltage V_{sw}, of FIG. 6 may be a drain-source voltage (e.g., the V_{sw}, of FIG. 4) of a switch (e.g., the first switch 252 of FIG. 2, the second switch 318 of FIG. 3, or the second transistor 431 of FIGS. 4 and 5).

Referring to FIGS. 4 and 6, the switch voltage V_{sw}, at the output terminal 439 of the second transistor 431 may swing according to the frequency (e.g., the operating frequency) of the RF signal provided by the power amplifier 420. In FIG. 6, “magnitude of switch voltage varies” may be expressed as “switch voltage swings.” The average of the switch voltage V_{sw}, may be expressed as an average voltage V_{avg}.

FIG. 7 is a view illustrating a change in capacitance C₀ₛ of a parasitic capacitor of a switch (e.g., the first switch 252 of FIG. 2, the second switch 318 of FIG. 3, or the second transistor 431 of FIGS. 4 and 5) as the switch voltage V_{sw}, of FIG. 6 swings. When the switch voltage V_{sw} of the output terminal 439 of the second transistor 431 is near 0[V], the thickness of the internal depletion region of the second transistor 431 may rapidly change according to the switch voltage. For example, referring to 700 in FIG. 7, when the switch voltage V_{sw} varies near 0[V](e.g., 0 to 35[V], as the thickness of the internal depletion region of the second transistor 431 changes rapidly according to the switch voltage, the capacitance Cₒₛₛ of the parasitic capacitor of the second transistor 431 may change rapidly. For example, as the switch voltage V_{sw} at the output terminal 439 of the second transistor 431 decreases in a range smaller than the transition voltage (or threshold voltage Vₜᵣ), the capacitance Cₒₛₛ of the parasitic capacitor of the second transistor 431 may increase rapidly. As the capacitance Cₒₛₛ of the parasitic capacitor of the second transistor 431 increases, the harmonic of the circuit may increase. Therefore, in order to reduce the harmonic component, it is necessary to keep the swing range of the switch voltage V_{sw} of the output terminal 439 of the second transistor 431 larger than the transition voltage (or threshold voltage Vₜᵣ).

Part (a) of FIG. 8 is a graph illustrating that a minimum value of the switching voltage V_{sw} is smaller than the transition voltage (or the threshold voltage Vₜᵣ). Part (b) of FIG. 8 is a view illustrating that a minimum value of the switching voltage V_{sw} is larger than the transition voltage (or the threshold voltage Vₜᵣ). As the bias voltage V_{bias} is applied to the output terminal (e.g., the output terminal 439) of the switch (e.g., the first switch 252 of FIG. 2, the second switch 318 of FIG. 3, or the second transistor 431 of FIGS. 4 and 5), the minimum value of the switching voltage V_{sw} may be maintained larger than the transition voltage (or the threshold voltage Vₜᵣ). As the minimum value of the switching voltage V_{sw} is maintained larger than the transition voltage (or the threshold voltage Vₜᵣ), harmonic components of the circuit may be reduced. For example, as the bias voltage is applied to the output terminal 439 of the second transistor 431 of the wireless power transmission device 500, the harmonic component of the circuit may decrease. The magnitude of the bias voltage applied to the output terminal 439 of the second transistor 431 may be larger than the average V_{avg} of the switching voltage of the output terminal 439 of the second transistor 431 when the bias voltage is not applied. The magnitude of the bias voltage applied to the output terminal 439 of the second transistor 431 may be determined so that the minimum value of the switching voltage V_{sw} of the output terminal 439 of the second transistor 431 is maintained larger than the transition voltage (or the threshold voltage Vₜᵣ) when the bias voltage is applied.

Referring to FIGS. 9 to 17, an embodiment of applying a bias voltage to an output terminal (e.g., the output terminal 439) of a switch (e.g., the first switch 252 of FIG. 2, the second switch 318 of FIG. 3, or the second transistor 431 of FIGS. 4 and 5) is described.

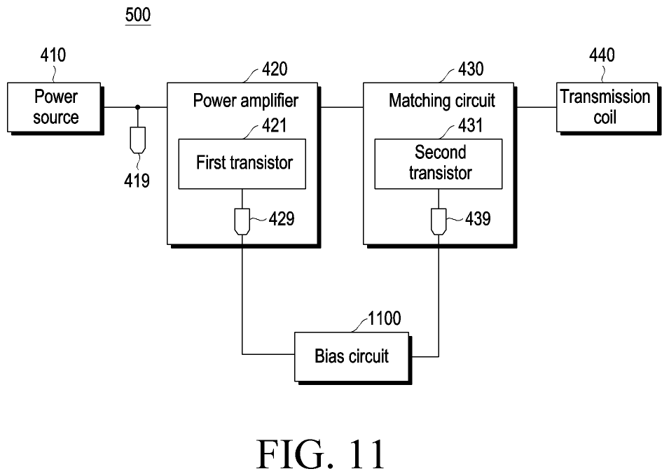

FIG. 9 is a block diagram illustrating a wireless power transmission device according to an embodiment of the disclosure. FIG. 10 is a block diagram illustrating a wireless power transmission device according to an embodiment of the disclosure. FIG. 11 is a block diagram illustrating a wireless power transmission device according to an embodiment of the disclosure. FIGS. 9, 10, and 11 may be described with reference to FIGS. 4 and 5.

Referring to FIGS. 4, 5, 9, 10, and 11, a wireless power transmission device 500 may include a power source 410, a power amplifier 420, a matching circuit 430, and a transmission coil 440.

Referring to FIG. 9, the wireless power transmission device 500 may include a bias source 900 for applying a bias voltage to the output terminal 439 of the second transistor 431. The bias source 900 may provide a DC voltage to the output terminal 439 of the second transistor 431. The bias source 900 is a component that provides a DC voltage to the output terminal 439 of the second transistor 431, and there is no limitation on the method of implementing the bias source 900.

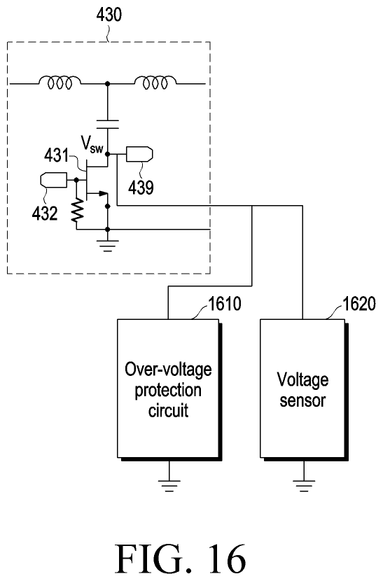

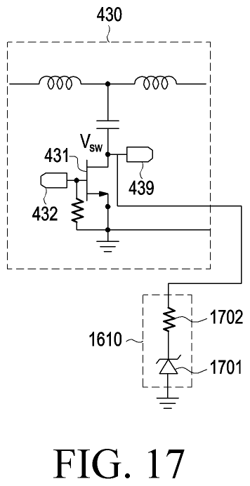

Referring to FIG. 10, the wireless power transmission device 500 may include a converter 1000 configured to provide a bias voltage to the output terminal 439 of the second transistor 431. The converter 1000 may be a DC-DC conversion circuit. For example, the converter 1000 may be a boost converter circuit. The implementation method of the converter 1000 is not limited. The input terminal of the converter 1000 may be connected to the power source 410. The output terminal of the converter 1000 may be connected to the output terminal 439 of the second transistor 431 included in the matching circuit 430. The converter 1000 may be connected to one end 419 of the power source 410 and convert power provided from the power source 410, providing a bias voltage to the output terminal 439 of the second transistor 431. The wireless power transmission device 500 may provide a bias voltage to the output terminal 439 of the second transistor 431 by controlling the converter 1000. For example, by controlling the converter 1000, the wireless power transmission device 500 may control the magnitude of the bias voltage provided to the output terminal 439 of the second transistor 431. As described below, the wireless power transmission device 500 may include a voltage sensor connected to the output terminal 439 of the second transistor 431. The wireless power transmission device 500 may set the magnitude of the bias voltage provided to the output terminal 439 of the second transistor 431 based on the average switching voltage of the output terminal 439 of the second transistor 431 sensed by the voltage sensor. The wireless power transmission device 500 may control the magnitude of the bias voltage provided to the output terminal 439 of the second transistor 431 by controlling the converter 1000 based on the sensing value of the voltage sensor. The voltage sensor is described below with reference to FIGS. 16 and 17.

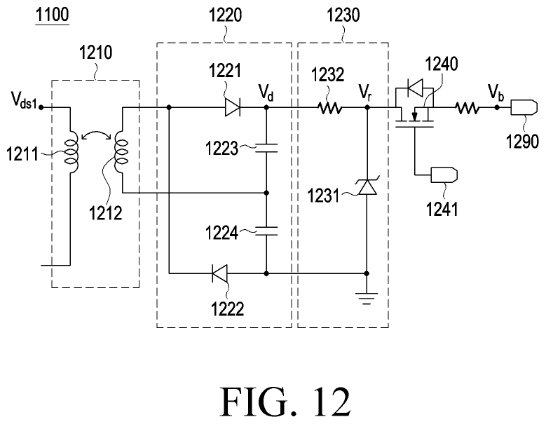

Referring to FIG. 11, the wireless power transmission device 500 may include a bias circuit 1100 configured to provide a bias voltage to the output terminal 439 of the second transistor 431. An input terminal of the bias circuit 1100 may be connected to an output terminal 429 (e.g., the first terminal) of the first transistor 421 included in the power amplifier 420. The output terminal of the bias circuit 1100 may be connected to the output terminal 439 (e.g., the second terminal) of the second transistor 431 included in the matching circuit 430. The bias circuit 1100 may provide a bias voltage to the output terminal 439 of the second transistor 431 based on the RF signal at the output terminal 429 of the first transistor 421. The bias circuit 1100 may rectify the RF signal at the output terminal 429 of the first transistor 421 and provide a bias voltage to the output terminal 439 of the second transistor 431. The bias circuit 1100 may be understood with reference to FIG. 12.

FIG. 12 is a circuit diagram illustrating a bias circuit according to an embodiment of the disclosure.

Referring to FIG. 12, a bias circuit 1100 may include a transformer 1210, a doubler 1220, a regulator 1230, and/or a switch 1240. The bias circuit 1100 may not include at least one of the transformer 1210, the doubler 1220, the regulator 1230, or the switch 1240.

The transformer 1210 may be connected to the output terminal 429 of the first transistor 421 of the power amplifier 420. The transformer 1210 may include a primary coil 1211 and a secondary coil 1212 that is magnetically coupled to the primary coil 1211. The first terminal of the primary coil 1211 of the transformer 1210 may be connected to the output terminal 429 of the first transistor 421 of the power amplifier 420. The transformer 1210 may receive an RF signal from the output terminal 429 of the first transistor 421 through the first terminal of the primary coil 1211. The first drain-source voltage V_{ds1} of the output terminal 429 of the first transistor 421 may be applied to the first terminal of the primary coil 1211 of the transformer 1210.

The primary coil 1211 and the secondary coil 1212 of the transformer 1210 may have a number of turns in a designated range. According to a ratio of the number of turns of the primary coil 1211 and the number of turns of the secondary coil 1212, a ratio of the first drain-source voltage V_{ds1} of the output terminal 429 of the first transistor 421 and the bias voltage V_{bias} provided to the output terminal 439 of the second transistor 431 may be determined. The numbers of turns of the primary coil 1211 and the secondary coil 1212 of the transformer 1210 may be determined according to the magnitude of the bias voltage to be provided to the output terminal 439 of the second transistor 431. The transformer 1210 may convert power provided to the primary coil 1211 through the primary coil 1211 and the secondary coil 1212. The transformer 1210 may transfer the power converted through the primary coil 1211 and the secondary coil 1212 to the doubler 1220 connected to the secondary coil 1212.

The doubler 1220 may be connected to the secondary coil 1212 of the transformer 1210. For example, referring to FIG. 12, the doubler 1220 may include a first diode 1221, a second diode 1222, a first capacitor 1223, and a second capacitor 1224. The doubler 1220 may rectify alternating current to direct current. The doubler 1220 may rectify power transferred through the secondary coil 1212 of the transformer 1210. The voltage V_{d} at the output terminal of the doubler 1220 may be twice the average of the voltage applied by the secondary coil 1212.

The regulator 1230 may be connected to the doubler 1220. The regulator 1230 may include a Zener diode 1231. The wireless power transmission device 500 may maintain the magnitude of the bias voltage provided to the output terminal 439 of the second transistor 431 in a designated range through the Zener diode 1231 included in the regulator 1230. By the Zener diode 1231, the voltage Vᵣ of the output terminal of the regulator 1230 may be maintained within the designated range. The regulator 1230 may include a resistor 1232 that prevents damage to the Zener diode 1231.

The switch 1240 may be connected to the regulator 1230. The switch 1240 may include a transistor. The wireless power transmission device 500 may control on/off of the switch 1240 by controlling the gate driver 1241. The wireless power transmission device 500 may provide a bias voltage to the output terminal 439 of the second transistor 431 by turning on the switch 1240. In the on state of the switch 1240, the bias voltage may be transferred to the output terminal 439 of the second transistor 431. The wireless power transmission device 500 may turn off the switch 1240 so as not to provide the bias voltage to the output terminal 439 of the second transistor 431. In the off state of the switch 1240, the bias voltage may not be transferred to the output terminal 439 of the second transistor 431. As described below, the wireless power transmission device 500 may include a voltage sensor connected to the output terminal 439 of the second transistor 431. The wireless power transmission device 500 may control the switch 1240 based on the sensing value of the voltage sensor. When the sensing value of the voltage sensor exceeds a reference value, the wireless power transmission device 500 may control the switch 1240 in an off state. The voltage sensor is described below with reference to FIGS. 16 and 17.

The magnitude of the bias voltage transferred to the output terminal 439 of the second transistor 431 in the on state of the switch 1240 may be larger than the average of the switch voltage of the output terminal 439 of the second transistor 431 in the off state of the switch 1240. As the magnitude of the bias voltage transferred to the output terminal 439 of the second transistor 431 in the on state of the switch 1240 is maintained larger than the average of the switch voltage of the output terminal 439 of the second transistor 431 in the off state of the switch 1240, the minimum value of the switching voltage of the output terminal 439 of the second transistor 431 in the on state of the switch 1240 may be maintained larger than the transition voltage (or threshold voltage Vₜᵣ). The numbers of turns of the primary coil 1211 and the secondary coil 1212 of the transformer 1210 may be determined so that the minimum value of the switching voltage of the output terminal 439 of the second transistor 431 is maintained larger than the transition voltage (or the threshold voltage Vₜᵣ) in the on state of the switch 1240.

The output terminal 1290 of the bias circuit 1100 may be connected to the output terminal 439 of the second transistor 431 of the matching circuit 430. The bias voltage may be transferred to the output terminal 439 of the second transistor 431 through the output terminal 1290 of the bias circuit 1100.

The bias circuit 1100 may provide a bias voltage to the output terminal 439 of the second transistor 431 based on the RF signal of the output terminal 429 of the first transistor 421 provided through the first terminal of the first primary coil 1211 of the transformer 1210. As described below, when an RF signal is provided to the primary coil 1211 of the transformer 1210 through a plurality of power amplifiers, the bias circuit 1100 may provide a bias voltage to the output terminal 439 of the second transistor 431 based on the plurality of RF signals provided to the primary coil 1211 of the transformer 1210.

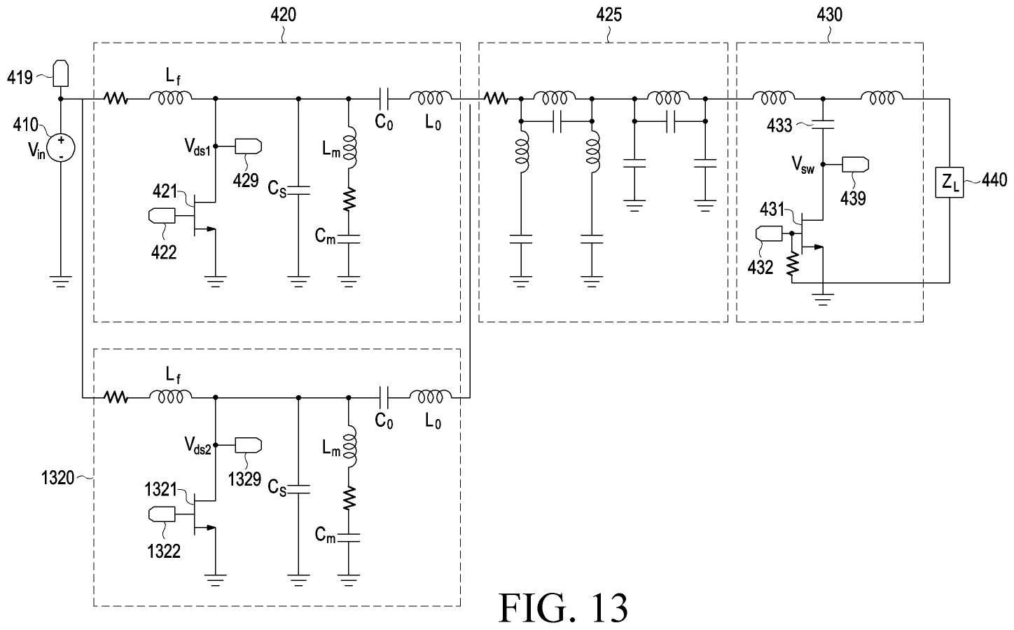

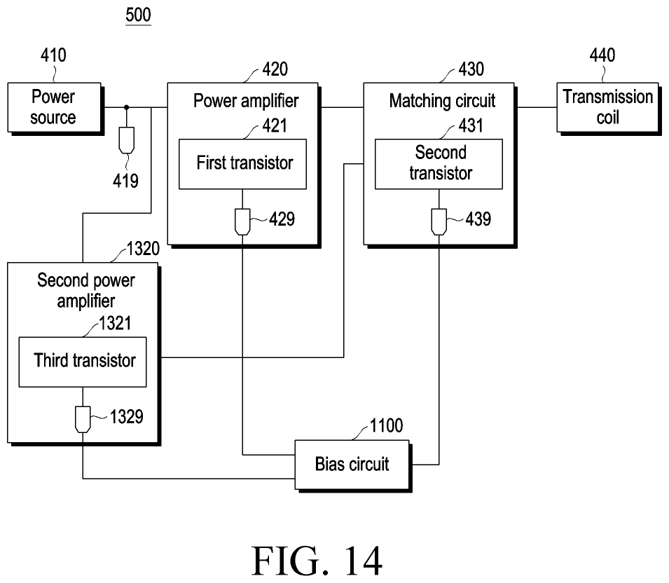

FIG. 13 is a circuit diagram illustrating a wireless power transmission device according to an embodiment of the disclosure. FIG. 14 is a block diagram illustrating a wireless power transmission device according to an embodiment of the disclosure.

FIGS. 13 and 14 are views illustrating an embodiment in which a plurality of power amplifiers are included in a wireless power transmission device.

The wireless power transmission device 500 of FIGS. 13 and 14 further includes a second power amplifier 1320 in addition to the configuration of the wireless power transmission device 500 of FIG. 11. Referring to FIGS. 13 and 14, the wireless power transmission device 500 may include a power source 410, a power amplifier 420 (e.g., a first power amplifier), a second power amplifier 1320, a matching circuit 430, a transmission coil 440, and a bias circuit 1100. Referring to FIG. 13, the wireless power transmission device 500 may include a harmonic filter 425.

The second power amplifier 1320 may be understood similarly to the power amplifier 420 (e.g., the first power amplifier). The second power amplifier 1320 may include a third transistor 1321. The second power amplifier 1320 may provide an RF signal (e.g., the second RF signal) based on a driving voltage provided from the power source 410 and an input signal provided to the third transistor 1321 through the third gate driver 1322. The second power amplifier 1320 may receive a driving voltage from a power source different from the power source 410.

Referring to FIG. 13, the voltage of the output terminal 1329 (e.g., the third terminal) of the third transistor 1321 may be referred to as a second drain-source voltage (e.g., “V_{ds2}”). In FIG. 13, the symbol corresponding to the output terminal 1329 of the third transistor 1321 may be understood to describe that another circuit may be connected to the output terminal 1329 of the third transistor 1321.

The matching circuit 430 may provide impedance matching between the transmission coil 440, the first power amplifier 420, and the second power amplifier 1320.

The bias circuit 1100 may be connected to the first power amplifier 420 and the second power amplifier 1320. The bias circuit 1100 may provide a bias voltage to the output terminal 439 of the second transistor 431 of the matching circuit 430 based on the first RF signal provided from the first power amplifier 420 and the second RF signal provided from the second power amplifier 1320.

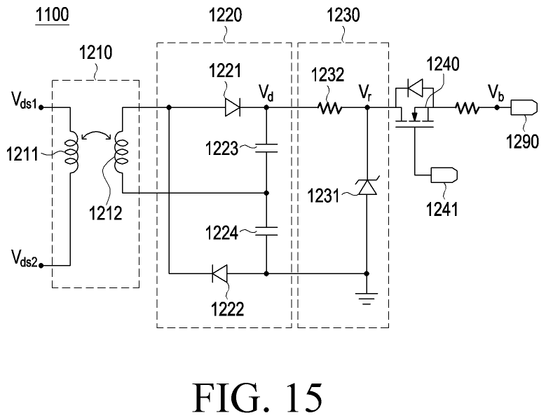

FIG. 15 is a circuit diagram illustrating a bias circuit according to an embodiment of the disclosure. FIG. 15 may be described with reference to FIGS. 13 and 14.

Referring to FIG. 15, in the wireless power transmission device 500 of FIGS. 13 and 14, a process of transferring a bias voltage to the output terminal 439 of the second transistor 431 may be understood.

In FIG. 12, an RF signal (e.g., the first RF signal) of the power amplifier 420 (e.g., the first power amplifier) may be provided only to the first terminal of the primary coil 1211 of the transformer 1210. In FIG. 15, an RF signal (e.g., the first RF signal) of the power amplifier 420 (e.g., the first RF signal) may be provided to the first terminal of the primary coil 1211 of the transformer 1210, and the second RF signal of the second power amplifier 1320 may be provided to the second terminal of the primary coil 1211 of the transformer 1210.

Referring to FIG. 15, the first terminal of the primary coil 1211 of the transformer 1210 of the bias circuit 1100 may be connected to the output terminal 429 of the first transistor 421 of the first power amplifier 420. The second terminal of the primary coil 1211 of the transformer 1210 of the bias circuit 1100 may be connected to the output terminal 1329 (e.g., the third terminal) of the third transistor 1321 of the second power amplifier 1320. The first RF signal of the first power amplifier 420 and the second RF signal of the second power amplifier 1320 may be alternately provided to the first and second terminals of the primary coil 1211 of the transformer 1210. The wireless power transmission device 500 may control the components of the wireless power transmission device 500 so that the first RF signal of the first power amplifier 420 and the second RF signal of the second power amplifier 1320 are alternately provided to the first and second terminals of the primary coil 1211 of the transformer 1210.

As shown in FIG. 12, the bias circuit 1100 of FIG. 15 may provide a bias voltage to the output terminal 439 of the second transistor 431 of the matching circuit 430 through the transformer 1210, the doubler 1220, the regulator 1230, and/or the switch 1240 based on the first RF signal of the first power amplifier 420 and the second RF signal of the second power amplifier 1320. FIG. 15 may be understood similarly to FIG. 12. Accordingly, in FIG. 15, descriptions overlapping the operation of FIG. 12 will be omitted. As the number of power amplifiers connected to the bias circuit 1100 increases, the bias voltage provided to the output terminal 439 of the second transistor 431 of the matching circuit 430 may increase. As the first power amplifier 420 and the second power amplifier 1320 are connected to different terminals of the primary coil 1211 of the transformer 1210 and alternately provide RF signals, the bias voltage provided to the output terminal 439 of the second transistor 431 of the matching circuit 430 may increase.

FIG. 16 is a view illustrating an over-voltage protection circuit and a voltage sensor according to an embodiment of the disclosure. FIG. 17 is a view illustrating an over-voltage protection circuit according to an embodiment of the disclosure. FIGS. 16 and 17 may be described with reference to FIGS. 4, 5, 9, 10, 11, 12, 13, and 14.

Referring to FIGS. 16 and 17, the wireless power transmission device 500 of FIGS. 4, 5, 9, 10, 11, 12, 13, and 14 may include an over-voltage protection circuit 1610 and a voltage sensor 1620.

The over-voltage protection circuit 1610 (OVP circuit) may be connected to the output terminal 439 of the second transistor 431 of the matching circuit 430. The over-voltage protection circuit 1610 may allow the voltage at the output terminal 439 of the second transistor 431 to be maintained in a predetermined range. For example, referring to FIG. 17, the over-voltage protection circuit 1610 may include a Zener diode 1701 and a resistor 1702 for preventing damage to the Zener diode 1701. The voltage at the output terminal 439 of the second transistor 431 may be limited within the capacitance range of the Zener diode 1701 included in the over-voltage protection circuit 1610. The over-voltage protection circuit 1610 of FIG. 17 is exemplary, and there is no limitation on the implementation method of the over-voltage protection circuit 1610 included in the wireless power transmission device 500.

The voltage sensor 1620 may be connected to the output terminal 439 of the second transistor 431 of the matching circuit 430. The wireless power transmission device 500 may identify the voltage (e.g., the switching voltage) of the output terminal 439 of the second transistor 431 of the matching circuit 430 through the voltage sensor 1620.

The wireless power transmission device 500 may set the magnitude of the bias voltage provided to the output terminal 439 of the second transistor 431 based on the average switching voltage of the output terminal 439 of the second transistor 431 sensed by the voltage sensor 1620. For example, the wireless power transmission device 500 may control the magnitude of the bias voltage provided to the output terminal 439 of the second transistor 431 by controlling the converter 1000 of FIG. 10 based on the sensing value of the voltage sensor 1620.

Based on the maximum value (or average value) of the switching voltage of the output terminal 439 of the second transistor 431 sensed by the voltage sensor 1620 exceeding a reference voltage, the wireless power transmission device 500 may control the components of the wireless power transmission device 500 so that the bias voltage is not provided to the output terminal 439 of the second transistor 431. For example, the wireless power transmission device 500 may control the switch 1240 of FIGS. 12 and 15 based on the sensing value of the voltage sensor 1620. The wireless power transmission device 500 may control the switch 1240 in an off state when the sensing value (e.g., the maximum value or the average value) of the voltage sensor 1620 exceeds the reference value.

Those skilled in the art may understand that the embodiments described in the disclosure may be applied organically to each other within an applicable range. In at least some of the embodiments described herein, the features may be combined/merged within a range in which such combination does not cause a technical contradiction. Those skilled in the art may understand that at least some operations of an embodiment described herein may be omitted, or that at least some operations of an embodiment and at least some operations of another embodiment may be organically connected. The order of at least some of the operations described in the disclosure may be changed.

According to an embodiment, a wireless power transmission device 500 may comprise a power source 410, a first power amplifier 420 configured to provide a first radio frequency RF signal based on a driving voltage provided from the power source 410, a transmission coil 440 configured to be used to transmit power to an outside based on the first RF signal, a matching circuit 430 configured to provide impedance matching between the transmission coil 440 and the first power amplifier 420, and a bias circuit 1100 configured to provide a bias voltage to the matching circuit 430. An input terminal of the bias circuit 1100 may be connected to the first terminal 429 of the first transistor 421 included in the first power amplifier 420. An output terminal 1290 of the bias circuit 1100 may be connected to a second terminal 439 of a second transistor 431 included in the matching circuit 430. The bias circuit 1100 may be configured to provide the bias voltage to the second terminal 439 of the second transistor 431 based on the first RF signal at the first terminal 429 of the first transistor 421.

According to an embodiment, the bias circuit 1100 may include a transformer connected to the first terminal 429 of the first transistor 421. The transformer 1210 may include a primary coil 1211 and a secondary coil 1212 magnetically coupled with the primary coil 1211.

According to an embodiment, the primary coil 1211 and the secondary coil 1212 of the transformer 1210 may have a number of turns in a designated range.

According to an embodiment, the wireless power transmission device 500 may comprise a second power amplifier 1320. A first terminal of the primary coil 1211 of the transformer 1210 may be connected to the first terminal 429 of the first transistor 421 of the first power amplifier 420. A second terminal of the primary coil 1211 of the transformer 1210 may be connected to a third terminal 1329 of a third transistor 1321 included in the second power amplifier 1320. The bias circuit 1100 may be configured to provide the bias voltage to the second terminal 439 of the second transistor 431 based on the first RF signal at the first terminal 429 of the first transistor 421 and a second RF signal at the third terminal 1329 of the third transistor 1321.

The bias circuit 1100 may further include a doubler 1220 connected to the secondary coil 1212 of the transformer 1210. The doubler 1220 may be configured to rectify power transferred through the secondary coil 1212.

According to an embodiment, the bias circuit 1100 may include a regulator 1230 connected to the doubler 1220. The regulator 1230 may include a first Zener diode 1231 configured to maintain a magnitude of the bias voltage in a designated range.

According to an embodiment, the bias circuit 1100 may include a switch 1240 connected to the regulator 1230. The bias voltage may be provided in an on state of the switch 1240.

According to an embodiment, a magnitude of the bias voltage provided through the bias circuit 1100 in the on state of the switch 1240 may be larger than an average of a voltage at the second terminal 439 of the second transistor 431 of the matching circuit 430 in an off state of the switch 1240.

According to an embodiment, the matching circuit 430 may include a shunt capacitor 433 connected to the second terminal 439 of the second transistor 431.

According to an embodiment, the wireless power transmission device 500 may comprise an over-voltage protection circuit 1610 connected to the second terminal 439 of the second transistor 431.

According to an embodiment, the over-voltage protection circuit 1610 may include a second Zener diode 1701.

According to an embodiment, the wireless power transmission device 500 may comprise a voltage sensor 1620 connected to the second terminal 439 of the second transistor 431.

According to an embodiment, the bias circuit 1100 may include a switch 1240. The switch 1240 may be configured to be controlled based on a voltage sensed by the voltage sensor 1620. The bias voltage may not be provided in an off state of the switch 1240.

According to an embodiment, a wireless power transmission device 500 may comprise a power source 410, a first power amplifier 420 configured to provide a first radio frequency RF signal based on a driving voltage provided from the power source 410, a transmission coil 440 configured to be used to transmit power to an outside based on the first RF signal, a matching circuit 430 configured to provide impedance matching between the transmission coil 440 and the first power amplifier 420, and a converter 1000 configured to provide a bias voltage to the matching circuit 430. An input terminal of the converter 1000 may be connected to the power source 410. An output terminal of the converter 1000 may be connected to a transistor 431 included in the matching circuit 430.

According to an embodiment, the wireless power transmission device 500 may comprise a voltage sensor 1620 configured to measure a voltage of a second terminal 439 of the transistor 431. A magnitude of the bias voltage provided by the converter 1000 may be set based on an average voltage of the second terminal 439 of the transistor 431 sensed by the voltage sensor 1620.

An embodiment of the disclosure and terms used therein are not intended to limit the technical features described in the disclosure to specific embodiments, and should be understood to include various modifications, equivalents, or substitutes of the embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

According to embodiments, each component of the above-described components may include a single entity or multiple entities. Some of the plurality of entities may be separately disposed in different components. According to embodiments, one or more of the above-described components may be omitted, or one or more other components may be added. Alternatively or additionally, a plurality of components may be integrated into a single component. In such a case, according to various embodiments, the integrated component may still perform one or more functions of each of the plurality of components in the same or similar manner as they are performed by a corresponding one of the plurality of components before the integration. According to embodiments, operations performed by components may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A wireless power transmission device, comprising:
a power source;
a first power amplifier configured to provide a first radio frequency (RF) signal based on a driving voltage provided from the power source;
a transmission coil configured to be used to transmit power to an outside based on the first RF signal;
a matching circuit configured to provide impedance matching between the transmission coil and the first power amplifier; and
a bias circuit configured to provide a bias voltage to the matching circuit,
wherein an input terminal of the bias circuit is connected to a first terminal of a first transistor included in the first power amplifier,
wherein an output terminal of the bias circuit is connected to a second terminal of a second transistor included in the matching circuit, and
wherein the bias circuit is configured to provide the bias voltage to the second terminal of the second transistor based on the first RF signal at the first terminal of the first transistor.

2. The wireless power transmission device of claim 1,
wherein the bias circuit includes a transformer connected to the first terminal of the first transistor, and
wherein the transformer includes a primary coil and a secondary coil magnetically coupled with the primary coil.

3. The wireless power transmission device of claim 2, wherein the primary coil and the secondary coil of the transformer have a number of turns in a designated range.

4. The wireless power transmission device of claim 2, further comprising:
a second power amplifier,
wherein a first terminal of the primary coil of the transformer is connected to the first terminal of the first transistor of the first power amplifier,
wherein a second terminal of the primary coil of the transformer is connected to a third terminal of a third transistor included in the second power amplifier, and
wherein the bias circuit is configured to provide the bias voltage to the second terminal of the second transistor based on the first RF signal at the first terminal of the first transistor and a second RF signal at the third terminal of the third transistor.

5. The wireless power transmission device of claim 2,
wherein the bias circuit further includes a doubler connected to the secondary coil of the transformer, and
wherein the doubler is configured to rectify power transferred through the secondary coil.

6. The wireless power transmission device of claim 5,
wherein the bias circuit further includes a regulator connected to the doubler, and
wherein the regulator includes a first Zener diode configured to maintain a magnitude of the bias voltage in a designated range.

7. The wireless power transmission device of claim 6,
wherein the bias circuit further includes a switch connected to the regulator, and
wherein the bias voltage is provided in an on state of the switch.

8. The wireless power transmission device of claim 7, wherein a magnitude of the bias voltage provided through the bias circuit in the on state of the switch is larger than an average of a voltage at the second terminal of the second transistor of the matching circuit in an off state of the switch.

9. The wireless power transmission device of claim 1, wherein the matching circuit further includes a shunt capacitor connected to the second terminal of the second transistor.

10. The wireless power transmission device of claim 1, further comprising:
an over-voltage protection circuit connected to the second terminal of the second transistor.

11. The wireless power transmission device of claim 10, wherein the over-voltage protection circuit includes a second Zener diode.

12. The wireless power transmission device of claim 1, further comprising a voltage sensor connected to the second terminal of the second transistor.

13. The wireless power transmission device of claim 12,
wherein the bias circuit includes a switch, wherein the switch is configured to be controlled based on a voltage sensed by the voltage sensor, and
wherein the bias voltage is not provided in an off state of the switch.

14. A wireless power transmission device comprising:
a power source;
a first power amplifier configured to provide a first radio frequency (RF) signal based on a driving voltage provided from the power source;
a transmission coil configured to be used to transmit power to an outside based on the first RF signal;
a matching circuit configured to provide impedance matching between the transmission coil and the first power amplifier; and
a converter configured to provide a bias voltage to the matching circuit,
wherein an input terminal of the converter is connected to the power source, and
wherein an output terminal of the converter is connected to a transistor included in the matching circuit.

15. The wireless power transmission device of claim 14, further comprising:
a voltage sensor configured to measure a voltage of a second terminal of the transistor, and
wherein a magnitude of the bias voltage provided by the converter is set based on an average voltage of the second terminal of the transistor sensed by the voltage sensor.
